(19) United States
(12) Patent Application Publication
(10) Pub. No.: US 2024/0224602 A1
(43) Pub. Date: Jul. 4, 2024

(54) DISPLAY APPARATUS

(71) Applicant: LG Display Co., Ltd., Seoul (KR)

(72) Inventors: Intae KO, Daegu (KR); AJung SONG, Daegu (KR)

(21) Appl. No.: 18/390,632

(22) Filed: Dec. 20, 2023

(30) Foreign Application Priority Data
Dec. 30, 2022 (KR) 10-2022-0191272

(51) Int. Cl. H10K 59/122; G09G 3/3225

(52) U.S. Cl. CPC H10K 59/122; G09G 3/3225; G09G 2300/0842

(57) ABSTRACT

Embodiments of the present specification may provide a display apparatus including a first protective layer disposed on a substrate, a second protective layer disposed on the first protective layer and having a plurality of first openings, a plurality of first electrodes disposed on the plurality of first openings, a bank disposed on the second protective layer and having a second opening in an area between two adjacent first electrodes among the plurality of first electrodes, a pattern structure disposed below the second opening, and a common organic layer disposed in an area including the plurality of first electrodes, the bank, and the pattern structure and connected to the plurality of first electrodes and a metal pattern of the pattern structure.

### CROSS-REFERENCE TO RELATED APPLICATION

This application claims priority from Korean Patent Application No. 10-2022-0191272, filed on Dec. 30, 2022, which is hereby incorporated by reference for all purposes as if fully set forth herein.

### BACKGROUND

### Technical Field

The present specification relates to a display apparatus.

### Description of the Related Art

With the development of information society, demands for display apparatuses for displaying images are increasing in various forms. Accordingly, various display apparatuses such as liquid crystal display (LCD) apparatuses, inorganic light-emitting display apparatuses, and organic light-emitting display (OLED) apparatuses have recently been used.

Among the display apparatuses, the OLED apparatuses are self-illuminating apparatuses and thus have a superior viewing angle, a high contrast ratio, and the like compared to the LCD apparatuses and can be decreased in weight and thickness and are advantageous in power consumption because a separate backlight is not required. In addition, the OLED apparatuses can be driven with a low direct current (DC) voltage, have a quick response time, and have low manufacturing costs.

### BRIEF SUMMARY

An aspect of the present specification is to provide a display apparatus capable of minimizing a side leakage current.

Another aspect of the present specification is to provide a display apparatus capable of preventing a non-driven sub-pixel among a plurality of sub-pixels having a common organic layer from emitting light due to a side leakage current.

Still another aspect of the present specification is to provide a display apparatus capable of improving a color reproduction range (color gamut) and display quality at a low gray scale by preventing unintended sub-pixels from emitting light.

Problems to be solved by embodiments of the present specification are not limited to the above-described problems, and other problems not described may be clearly understood by those of ordinary skill in the art from the following description.

In an aspect, an embodiment of the present specification may provide a display apparatus including a first protective layer disposed on a substrate, a second protective layer disposed on the first protective layer and having a plurality of first openings, a plurality of first electrodes disposed on the plurality of first openings, a bank disposed on the second protective layer and having a second opening in an area between two adjacent first electrodes among the plurality of first electrodes, a metal pattern disposed below the second opening, and a common organic layer disposed in an area including the plurality of first electrodes, the bank, and the metal pattern and connected to the plurality of first electrodes and the metal pattern.

In another aspect, an embodiment of the present specification may provide a display apparatus including a first protective layer disposed on a substrate, a second protective layer located on the first protective layer and having a plurality of first openings and a second opening, a plurality of first electrodes located on the plurality of first openings, a bank covering the second protective layer and having a plurality of third openings exposing the plurality of first electrodes and a fourth opening overlapping the second opening, and a common organic layer located in on the plurality of first electrodes and the bank and disposed along a surface curve of an area including the plurality of third openings and the fourth opening.

### Advantageous Effects

According to embodiments of the present specification, there is an effect of providing a display apparatus capable of reducing a side leakage current by allowing a current flowing through a common organic layer to be discharged through a metal pattern by forming an opening in a bank in an area between adjacent sub-pixels, arranging the metal pattern below the opening of the bank, and applying a ground voltage to the metal pattern.

According to embodiments of the present specification, there is an effect of providing a display apparatus capable of reducing a side leakage current by increasing a length of a leakage current transmission path by forming an opening in a second protective layer below a bank in an area between adjacent sub-pixels, and forming an opening overlapping the opening of the second protective layer in the bank to make the surface irregularities large, and disposing a common organic layer thereon. Accordingly, a low-power display apparatus can be provided.

According to embodiments of the present specification, there is an effect of providing a display apparatus capable of improving a color reproduction range by reducing a side leakage current and thus minimizing an unintended light-emitting element from emitting light, and improving display quality by minimizing spots or color abnormalities from being visually recognized when an image of a low gray scale is displayed.

The effects of the present specification are not limited to the above-described effects, and other effects not described may be clearly understood from the following description by those of ordinary skill in the art.

### BRIEF DESCRIPTION OF THE SEVERAL VIEWS OF THE DRAWINGS

The above and other aspects, features, and advantages of the present disclosure will be more apparent from the following detailed description taken in conjunction with the accompanying drawings, in which:

FIG. 1 is a view illustrating a schematic configuration of a display apparatus according to embodiments of the present specification;

FIG. 2 is an equivalent circuit diagram of a sub-pixel in the display apparatus according to embodiments of the present specification;

FIG. 3 is an exemplary plan view of the display apparatus according to embodiments of the present specification;

FIG. 4 is a view illustrating an example of a cross section taken along line A-A′ of FIG. 3;

FIG. 5 is a view illustrating an example of a cross section taken along line B-B′ of FIG. 3;

FIG. 6 is a view illustrating that light emitted from the display apparatus according to embodiments of the present specification is reflected by an inclined portion of a first electrode;

FIG. 7 is a view illustrating another example of the cross section taken along line A-A′ of FIG. 3;

FIG. 8 is a view illustrating another example of the cross section taken along line B-B′ of FIG. 3;

FIG. 9 is a plan view illustrating another example of the display apparatus according to embodiments of the present specification;

FIG. 10 is a plan view illustrating still another example of the display apparatus according to embodiments of the present specification;

FIG. 11 is a view illustrating an example of a cross section taken along line C-C′ of FIG. 10;

FIG. 12 is a plan view illustrating yet another example of the display apparatus according to embodiments of the present specification;

FIG. 13A is a cross-sectional view of a display apparatus according to a comparative example of the present specification;

FIG. 13B is a schematic representation of FIG. 13A;

FIGS. 14 and 15 are views showing effects of the present specification in contrast to FIG. 13A and FIG. 13B;

FIGS. 16 and 17 are exemplary cross-sectional views of the display apparatus according to embodiments of the present specification; and

FIG. 18 is a plan view illustrating emission parts and a non-emission part of the display apparatus according to embodiments of the present disclosure.

### DETAILED DESCRIPTION

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present disclosure, detailed descriptions of well-known functions and components incorporated herein will be omitted when it is determined that the description may make the subject matter in some embodiments of the present disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the present disclosure. Each of these terms is not used to define essence, order, sequence, or number of elements, etc., but is used merely to distinguish the corresponding element from other elements.

When it is mentioned that a first element “is connected or coupled to”, “contacts or overlaps”, etc., a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc., each other via a fourth element. Here, the second element may be included in at least one of two or more elements that “are connected or coupled to”, “contact or overlap”, etc., each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes, etc., are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Hereinafter, various embodiments of the present specification will be described in detail with reference to the accompanying drawings.

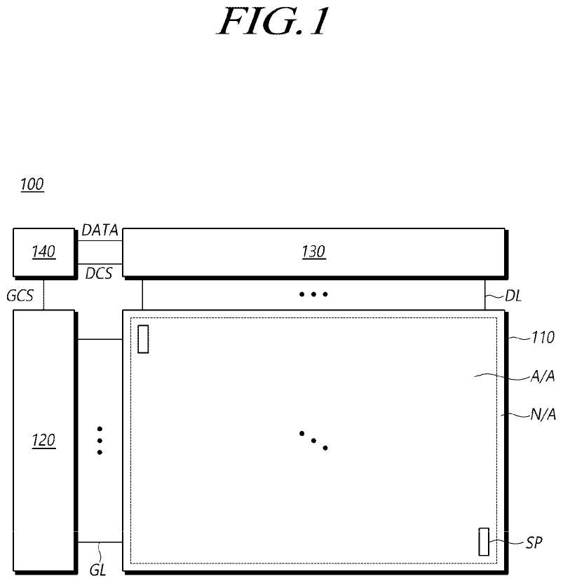

FIG. 1 is a view illustrating a schematic configuration of a display apparatus according to embodiments of the present specification.

Referring to FIG. 1, the display apparatus 100 according to embodiments of the present specification includes a display panel 110 that includes an active area A/A in which a plurality of sub-pixels SP are disposed, and a non-active area N/A located outside the active area A/A. In addition, the display apparatus may include a gate driving circuit 120, a data driving circuit 130, a controller 140, and the like for driving various signal lines or the like disposed in the display panel 110.

In the display panel 110, a plurality of gate lines GL and a plurality of data lines DL are disposed, and the sub-pixel SP is disposed in an area in which the gate lines GL and the data lines DL overlap.

The gate driving circuit 120 may be controlled by the controller 140, and may control driving timings of the plurality of sub-pixels SP by sequentially outputting a scan signal to the plurality of gate lines GL disposed in the display panel 110.

The gate driving circuit 120 may include one or more gate driver integrated circuits (GDICs), and may be located on only one side of the display panel 110, or may be located on both sides of thereof according to a driving method.

Each of the GDICs may be connected to a bonding pad of the display panel 110 by a tape automated bonding (TAB) method or a chip-on-glass (COG) method. Alternatively, each GDIC may be implemented as a gate-in-panel (GIP) type and disposed directly on the display panel 110 or may be integrated and disposed on the display panel 110 in some cases. Further, each GDIC may be implemented by a chip-on-film (COF) method in which each GDIC is mounted on a film connected to the display panel 110.

The data driving circuit 130 receives image data from the controller 140 and converts the image data into an analog data voltage. In addition, the data driving circuit 130 outputs the data voltage to the respective data lines DL according to the timing at which the scan signal is applied through the gate lines GL, so that each of the sub-pixels SP expresses a brightness corresponding to the image data.

The data driving circuit 130 may include one or more source driver integrated circuits (SDICs).

Each of the SDICs may include a shift register, a latch circuit, a digital-to-analog converter, an output buffer, and the like.

Each SDIC may be connected to the bonding pad of the display panel 110 by a tape automated bonding (TAB) method or a chip-on-glass (COG) method. Alternatively, each SDIC may be disposed directly on the display panel 110, or may be integrated and disposed on the display panel 110 in some cases. Further, each SDIC may be implemented by a chip-on-film (COF) method, and in this case, the SDIC may be mounted on a film connected to the display panel 110 and electrically connected to the display panel 110 through wirings on the film.

The controller 140 may supply various control signals to the gate driving circuit 120 and the data driving circuit 130, and control operations of the gate driving circuit 120 and the data driving circuit 130.

The controller 140 may be mounted on a printed circuit board, a flexible printed circuit, or the like and electrically connected to the gate driving circuit 120 and the data driving circuit 130 through the printed circuit board, the flexible printed circuit, or the like.

The controller 140 may control the gate driving circuit 120 to output the scan signal according to the timing implemented in each frame, convert externally received image data to match a data signal format used by the data driving circuit 130, and output the converted image data to the data driving circuit 130.

The controller 140 may receive various timing signals including a vertical synchronization signal VSYNC, a horizontal synchronization signal HSYNC, an input data enable signal DE, a clock signal CLK, and the like from the outside (e.g., a host system).

The controller 140 may generate various control signals by using the various timing signals received from the outside, and may output the control signals to the gate driving circuit 120 and the data driving circuit 130.

As an example, in order to control the gate driving circuit 120, the controller 140 may output various gate control signals GCS including a gate start pulse GSP, a gate shift clock GSC, a gate output enable signal GOE, and the like.

Here, the gate start pulse GSP controls an operation start timing of one or more GDICs constituting the gate driving circuit 120. The gate shift clock GSC, which is a clock signal commonly input to one or more GDICs, controls a shift timing of the scan signal. The gate output enable signal GOE specifies timing information on one or more GDICs.

In addition, in order to control the data driving circuit 130, the controller 140 may output various data control signals DCS including a source start pulse SSP, a source sampling clock SSC, a source output enable signal SOE, and the like.

Here, the source start pulse SSP controls a data sampling start timing of one or more SDICs constituting the data driving circuit 130. The source sampling clock SSC is a clock signal for controlling a data sampling timing for each of the SDICs. The source output enable signal SOE controls an output timing of the data driving circuit 130.

The display apparatus may further include a power management integrated circuit for supplying various voltages or currents to the display panel 110, the gate driving circuit 120, the data driving circuit 130, and the like or controlling the various voltages or currents to be supplied thereto.

Each of the sub-pixels SP may be located at an overlap between the gate lines GL and the data lines DL and a liquid crystal or a light-emitting element may be disposed according to the type of the display apparatus.

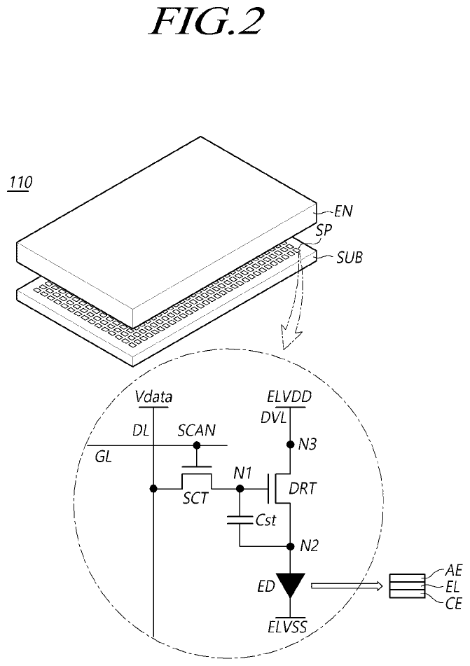

FIG. 2 is an equivalent circuit diagram of the sub-pixel SP, in the display panel 110 according to embodiments of the present specification.

Referring to FIG. 2, the display panel 110 according to embodiments of the present specification may include a substrate SUB and an encapsulation layer EN. Each of the sub-pixels SP disposed on the substrate SUB of the display panel 110 may include a light-emitting element ED, a driving transistor DRT for driving the light-emitting element ED, a scan transistor SCT for transmitting a data voltage Vdata to a first node N1 of the driving transistor DRT, and a storage capacitor Cst for maintaining a constant voltage during one frame.

The driving transistor DRT may include the first node N1 to which the data voltage may be applied, a second node N2 electrically connected to the light-emitting element ED, and a third node N3 to which a driving voltage ELVDD is applied from a driving voltage line DVL. In the driving transistor DRT, the first node N1 may be a gate node, the second node N2 may be a source node or a drain node, and the third node N3 may be the drain node or the source node.

The light-emitting element ED may include a first electrode AE, an emission layer EL, and a second electrode CE. The first electrode AE may be a pixel electrode disposed in each sub-pixel SP, and may be electrically connected to the second node N2 of the driving transistor DRT of each sub-pixel SP. The second electrode CE may be a common electrode commonly disposed in the plurality of sub-pixels SP, and a base voltage ELVSS may be applied to the second electrode CE.

For example, the first electrode AE may be an anode. The second electrode CE may be a cathode. The first electrode AE may be a pixel electrode, and the second electrode CE may be a common electrode. On the contrary, the first electrode AE may be a common electrode, and the second electrode CE may be a pixel electrode. Hereinafter, for convenience of description, in the embodiments of the present specification, it is assumed that the first electrode AE is a pixel electrode and the second electrode CE is a common electrode.

For example, the light-emitting element ED may be an organic light-emitting diode (OLED), an inorganic light-emitting diode, or a quantum dot light-emitting element. In this case, when the light-emitting element ED is an organic light-emitting diode, the emission layer EL of the light-emitting element ED may include an organic emission layer including an organic material.

The scan transistor SCT may be on/off controlled by a scan signal SCAN, which is a gate signal, applied via the gate line GL and be electrically connected between the first node N1 of the driving transistor DRT and the data line DL.

The storage capacitor Cst may be electrically connected between the first node N1 and second node N2 of the driving transistor DRT.

Each sub-pixel SP may have a 2T (transistor) 1C (capacitor) structure that includes two transistors DRT and SCT and one capacitor Cst as shown in FIG. 2 and, in some cases, each sub-pixel SP may further include one or more transistors or one or more capacitors. Embodiments of the present specification are not limited thereto.

The storage capacitor Cst is not a parasitic capacitor (e.g., Cgs or Cgd) which is an internal capacitor that may be present between the first node N1 and the second node N2 of the driving transistor DRT but may be an external capacitor intentionally designed outside the driving transistor DRT.

Each of the driving transistor DRT and the scan transistor SCT may be an n-type transistor or a p-type transistor.

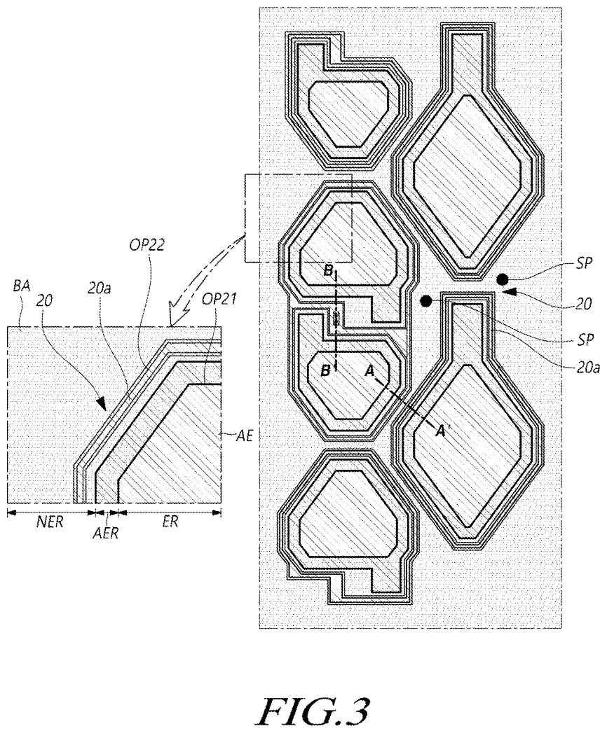

FIG. 3 is an exemplary plan view of the display apparatus according to embodiments of the present specification.

FIG. 3 shows only the first electrode AE, a pattern or pattern structure 20, a bank BA, and a second opening OP22 and a fourth opening OP21 of the bank BA among components of the display apparatus to simplify the drawing. The pattern structure 20 includes both conductive portions 20A and insulative portions SP. The conductive portions 20A, which may be referred to as metal patterns 20A in this disclosure are a plurality of leakage current portions, where each portion is spaced from an adjacent portion by an opening 101. The material may be metal or other suitable conductive material. The insulative portions SP are spacer structures SP, that are formed between adjacent sub-pixels as can be seen in FIG. 3. The spacer structures SP are formed in a non-emission area NER of the device.

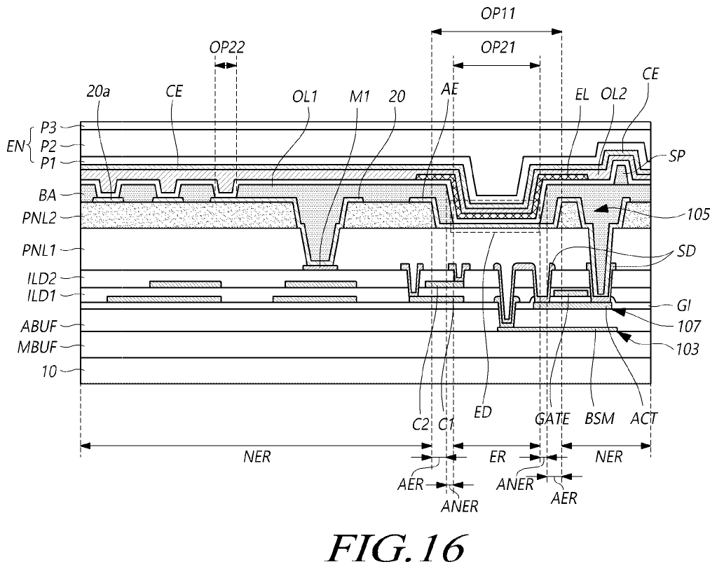

The pattern 20 includes a plurality of portions 20a, SP. Some of the plurality of portions are in the second opening and others are spaced from the second opening and aligned with a trench of the transistor. See FIG. 16.

Referring to FIG. 3, the substrate may include a plurality of emission areas ER corresponding to the plurality of sub-pixels. The emission area ER may be exposed by the fourth opening OP21 of the bank BA.

An additional emission area AER may be disposed around the emission area ER. The additional emission area AER may surround a periphery of the emission area ER. The additional emission area AER may have the form of a side ring surrounding the emission area ER. A non-emission area NER may be disposed outside the emission area ER and the additional emission area AER. The non-emission area NER may surround a periphery of the additional emission area AER. The bank BA may be disposed in the additional emission area AER and the non-emission area NER. The bank BA may block light from being generated in the non-emission area NER. Although not shown in the drawings, the non-emission area may be formed between the emission area ER and the additional emission area AER, and the emission area ER and the additional emission area AER may be distinguished by the non-emission area.

Each of the plurality of sub-pixels may be defined as a minimum unit area that emits light. The plurality of sub-pixels may include, for example, a red sub-pixel Red SP, a green sub-pixel Green SP, and a blue sub-pixel Blue SP. In addition, the plurality of sub-pixels may further include a white sub-pixel White SP.

The light-emitting element may be disposed in each of the emission areas ER. The light-emitting element may include the first electrode AE, an emission layer, a common organic layer, and a second electrode.

The first electrode AE may be disposed in the emission area ER of the sub-pixel and the additional emission area AER around the emission area ER. In addition, the first electrode AE may be disposed in the non-emission area NER around the additional emission area AER. The bank BA may cover the first electrode AE disposed in the additional emission area AER and the non-emission area NER.

The metal pattern 20A may be disposed around the first electrode AE in the non-emission area NER between adjacent sub-pixels. The metal pattern 20A may be located between adjacent first electrodes AE. The metal pattern 20A may be disposed on an outer side of the first electrode AE to surround the first electrode AE while being spaced apart from the first electrode AE. The metal pattern 20A may include the same material as the first electrode AE.

The metal pattern 20A may be exposed by the second opening OP22 of the bank BA. The common organic layer formed above the metal pattern 20A may be connected to the metal pattern 20A. When the display apparatus is driven, a ground voltage may be supplied to the metal pattern 20A. Accordingly, a leakage current flowing along the common organic layer is discharged through the metal pattern 20A, so that the leakage current flowing along the common organic layer of the sub-pixel may be suppressed or prevented from being transmitted to another neighboring sub-pixel.

The metal pattern 20A may be disposed along a contour corresponding to a shape of the entire or partial outer periphery of at least one of the first electrodes AE. Accordingly, an area, in which the metal pattern 20A is disposed, between two adjacent first electrodes AE may be reduced in size as much as possible.

The metal pattern 20A may be disposed to surround an outer periphery of each of, for example, two adjacent first electrodes AE. In this case, two metal patterns 20A are disposed between two adjacent first electrodes AE to form a double discharge path, thereby increasing a discharge effect of the leakage current.

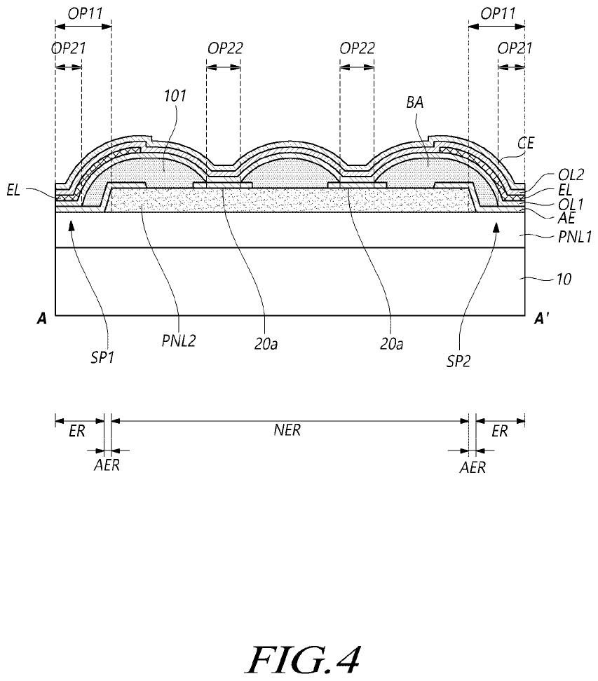

FIG. 4 is a view illustrating an example of a cross section taken along line A-A′ of FIG. 3.

Referring to FIG. 4, the display apparatus may include a substrate 10. A circuit layer may be disposed on one surface of the substrate 10.

The circuit layer may include a pixel circuit connected to wirings such as data lines, gate lines, power lines, and the like, a gate driving part connected to the gate lines, and the like. The circuit layer may include circuit elements such as a transistor implemented as a thin-film transistor (TFT), a capacitor, and the like. The wirings and circuit elements of the circuit layer may be implemented using a plurality of insulating layers, two or more metal layers separated with the insulating layer interposed therebetween, and an active layer including a semiconductor material.

A first protective layer PNL1 may be disposed on the substrate 10.

The first protective layer PNL1 may include a first planarization layer. The first protective layer PNL1 may planarize one surface of the substrate 10 on which the circuit layer is formed. Although FIG. 4 illustrates a case in which the first protective layer PNL1 has a single-layer structure, the first protective layer PNL1 may be configured as multiple layers as necessary as long as one surface of the substrate 10 on which the circuit layer is formed may be planarized.

A second protective layer PNL2 may be disposed on the first protective layer PNL1. The second protective layer PNL2 may include a second planarization layer. A portion of the second protective layer PNL2 corresponding to the emission area ER and the additional emission area AER of the sub-pixel may be open to form a first opening OP11. In the emission area ER, a portion of an upper surface of the first protective layer PNL1 may be exposed through the first opening OP11 of the second protective layer PNL2. In the additional emission area AER, a side surface (an inclined surface) of the second protective layer PNL2 may be exposed by the first opening OP11. The first opening OP11 may have a tapered shape of which a width decreases as it approaches the upper surface of the first protective layer PNL1, and the side surface (the inclined surface) of the second protective layer PNL2 exposed by the first opening OP11 may have an inclination angle other than 90 degrees.

The first electrode AE may be disposed in an area including the first opening OP11 of the second protective layer PNL2. The first electrode AE may be disposed on the upper surface of the first protective layer PNL1 exposed by the first opening OP11. In addition, the first electrode AE may be disposed on the side surface (the inclined surface) of the second protective layer PNL2 exposed by the first opening OP11.

The first electrode AE may include an inclined portion disposed on the side surface (the inclined surface) of the second protective layer PNL2. The inclined portion of the first electrode AE may be disposed in the additional emission area AER. The inclined portion of the first electrode AE may reflect light generated from the emission layer EL of the emission area ER and serve to increase light extraction efficiency.

The metal pattern 20A may be disposed on the second protective layer PNL2 in the non-emission area NER between adjacent sub-pixels SP1 and SP2. The metal pattern 20A may be located between adjacent first electrodes AE. The metal pattern 20A may be disposed on the same layer as the first electrode AE. The metal pattern 20A may be formed together with the first electrode AE when the first electrode AE is formed. The metal pattern 20A may include the same material as the first electrode AE.

The bank BA may be disposed on the second protective layer PNL2 while covering a portion of the first electrode AE. The bank BA may cover the inclined portion of the first electrode AE. The bank BA may cover an end of the first electrode AE.

The bank BA may have the fourth opening OP21 exposing the emission area ER of the sub-pixel. At least a portion of the first electrode AE disposed on the first protective layer PNL1 exposed through the first opening OP11 of the second protective layer PNL2 may be exposed by the fourth opening OP21 of the bank BA.

The second opening OP22 may be formed in the bank BA in the non-emission area NER between the adjacent sub-pixels SP1 and SP2. At least a portion of the metal pattern 20A may be exposed through the second opening OP22 of the bank BA.

Organic layers OL1, EL, and OL2 may be disposed on the first electrode AE, the bank BA, and the metal pattern 20A. The second electrode CE may be disposed on the organic layers OL1, EL, and OL2. The second electrode CE may be a cathode.

The organic layers OL1, EL, and OL2 may include the emission layer EL. In addition, the organic layers OL1, EL, and OL2 may include at least one of a first common organic layer OL1 and a second common organic layer OL2 respectively disposed below and above the emission layer EL.

For color display, the emission layer EL is separately formed for each of the red sub-pixel Red SP, the green sub-pixel Green SP, and the blue sub-pixel Blue SP. The emission layer EL may be formed of an organic emission layer having a color of a corresponding sub-pixel. The emission layer EL may include an organic material including a fluorescent or phosphorescent material emitting red, green, blue, or white light. The emission layer EL may be a low molecular weight organic material or a high molecular weight organic material. The emission layer EL may be generated using a deposition method using a shadow mask.

The first common organic layer OL1 may include a hole injection layer (HIL) and/or a hole transport layer (HTL). The second common organic layer OL2 may include an electron transport layer (ETL) and/or an electron injection layer (EIL).

In the red sub-pixel Red SP, in which the emission area ER in an area between the first and second electrodes AE and CE is formed relatively higher than those of other color sub-pixels according to process conditions, in order to match a light emission height, an auxiliary hole transport layer may be further provided between the hole transport layer (HTL) and a red emission layer Red EL. A position of an emission layer at which the maximum wavelength is obtained may be differently set between the first and second electrodes AE and CE for each light emission color of the emission layer EL. The red emission layer Red EL may be located at the highest height, a green emission layer Green EL may be located at the second-highest height, and a blue emission layer Blue EL may be located at the lowest height. Accordingly, the green sub-pixel Green SP may further include an auxiliary hole transport layer between the hole transport layer (HTL) and the green emission layer Green EL, and the auxiliary hole transport layer provided in the green sub-pixel Green SP may have a thickness less than that of an auxiliary hole transport layer of the red sub-pixel Red SP.

When the shadow mask has a large area, the shadow mask may sag due to a weight thereof, and thus may cause deterioration in a yield rate when used multiple times. Thus, the other organic layers excluding the emission layer EL may be continuously formed in common in the plurality of sub-pixels without the shadow mask.

The first common organic layer OL1 may be in contact with the first electrode AE in the fourth opening OP21 of the bank BA. The light-emitting element may be configured by the first electrode AE, the first common organic layer OL1, the emission layer EL, the second common organic layer OL2, and the second electrode CE in the fourth opening OP21 of the bank BA. The Light-emitting element of first and second sub-pixels SP1 and SP2 may be configured in the emission areas ER, respectively.

The first common organic layer OL1 may be in contact with the metal pattern 20A in the second opening OP22 of the bank BA. When the display apparatus is driven, a ground voltage may be supplied to the metal pattern 20A. Accordingly, a leakage current flowing along the first common organic layer OL1 of the first sub-pixel SP1 may be discharged through the metal pattern 20A, thereby preventing the leakage current from flowing to the neighboring second sub-pixel SP2. In addition, a leakage current flowing along the first common organic layer OL1 of the second sub-pixel SP2 may be discharged through the metal pattern 20A, thereby preventing the leakage current from flowing to the neighboring first sub-pixel SP1.

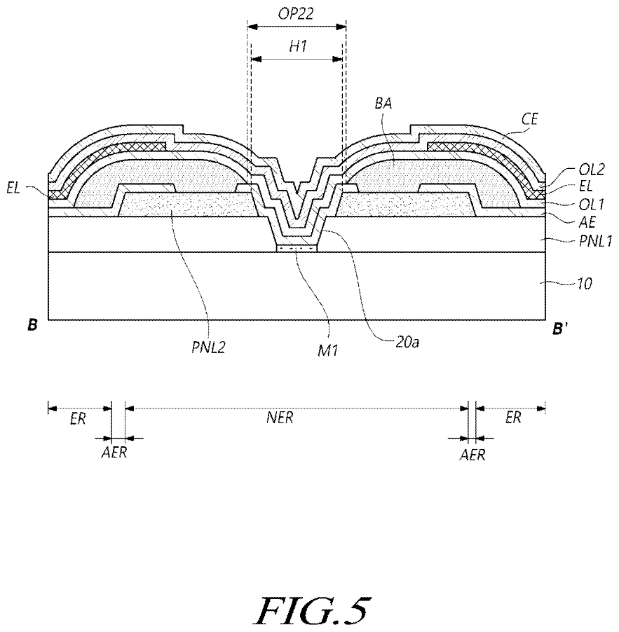

FIG. 5 is a view illustrating an example of another cross section taken along line B-B′ of FIG. 3 according to the embodiment of the present specification, showing a portion in which the metal pattern 20A is connected to a ground line M1 of the substrate 10.

Referring to FIG. 5, a contact hole H1 may be formed in the first and second protective layers PNL1 and PNL2 in the non-emission area NER. The contact hole H1 may be disposed between neighboring first electrodes AE. The ground line M1 of the substrate 10 may be exposed through the contact hole H1.

The metal pattern 20A may be disposed on the ground line M1, which is exposed by the contact hole H1, and a sidewall of the contact hole H1. The metal pattern 20A may be connected to the ground line M1 through the contact hole H1. The metal pattern 20A is in contact with the ground line M1, and may be directly connected to the ground line M1.

The second opening OP22 of the bank BA may overlap the contact hole H1. In this case, at least a portion of the metal pattern 20A disposed on the ground line M1 and the sidewall of the contact hole H1 may be exposed through the second opening OP22 of the bank BA, and the first common organic layer OL1 may be in direct contact with the metal pattern 20A in the contact hole H1.

Although not shown in the drawing, in another example, the second opening OP22 of the bank BA may not overlap the contact hole H1. In this case, the bank BA may cover the metal pattern 20A disposed on the ground line M1 and the sidewall of the contact hole H1 and fill the contact hole H1.

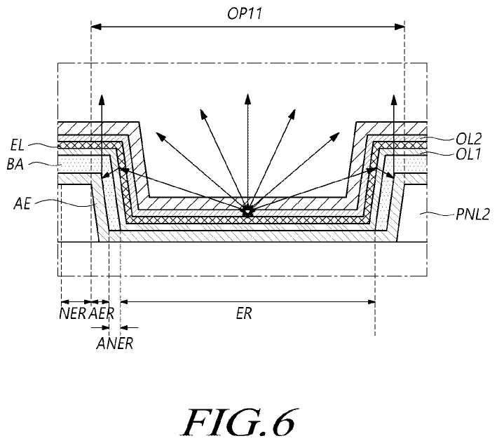

FIG. 6 is a view for describing that light emitted from the emission layer is reflected by the inclined portion of the first electrode AE according to embodiments of the present specification.

Referring to FIG. 6, the light emitted from the emission layer EL is radiated in various directions without directivity in a specific direction. Light reaching the inclined portion of the first electrode AE disposed on the inclined surface of the second protective layer PNL2 exposed by the first opening OP11 may be reflected by the inclined portion of the first electrode AE and emitted to the outside of the display apparatus. Accordingly, the light extraction efficiency is improved, and an amount of light emitted from the display apparatus is increased, thereby increasing luminance. In addition, since a sufficient amount of light may be emitted at a low voltage, it is possible to lower power consumption. A viewing angle and luminance are also increased according to the improvement of light efficiency, thereby providing a wide viewing angle.

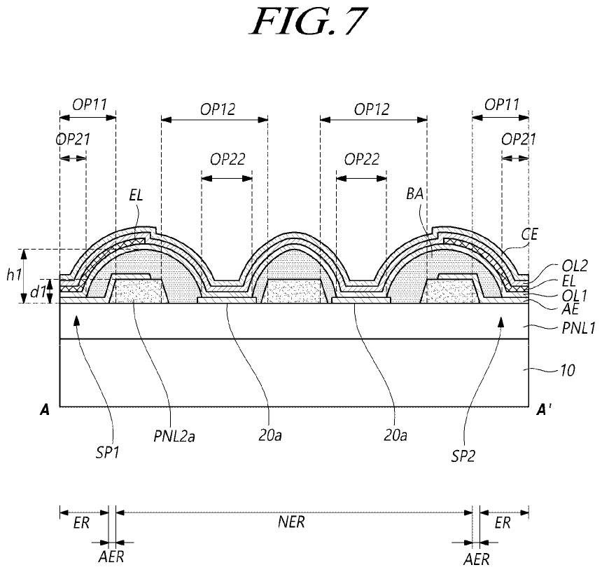

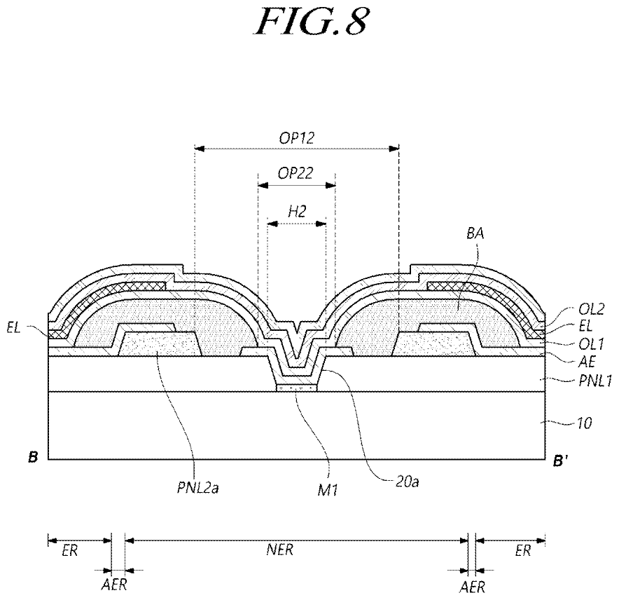

FIG. 7 is a view illustrating another example of the cross section taken along line A-A′ of FIG. 3, and FIG. 8 is a view illustrating another example of the cross section taken along line B′-B of FIG. 3.

Referring to FIG. 7, in the non-emission area NER between adjacent sub-pixels, a portion of a second protective layer PNL2a may be open to form a third opening OP12. The third opening OP12 may be located between adjacent first electrodes AE. The third opening OP12 may be formed together with the first opening OP11 when the first opening OP11 is formed.

A portion of the first protective layer PNL1 may be exposed through the third opening OP12 of the second protective layer PNL2a.

At least a portion of a metal pattern 20a may be disposed on the first protective layer PNL1 exposed by the third opening OP12 of the second protective layer PNL2a. The embodiment of FIG. 7 is different from the embodiment of FIG. 4 in that the second protective layer PNL2a further includes the third opening OP12, and the metal pattern 20a is disposed on the first protective layer PNL1 rather than on the second protective layer PNL2a.

The bank BA may cover a portion of the second protective layer PNL2a. The bank BA may include a fourth opening OP21. A portion of the first electrode AE may be exposed through the fourth opening OP21 of the bank BA.

The bank BA may include a second opening OP22. The metal pattern 20a may be exposed through the second opening OP22 of the bank BA. The second opening OP22 of the bank BA may overlap the third opening OP12 of the second protective layer PNL2a. As described above, in the non-emission area NER, when the third opening OP12 overlapping the second opening OP22 of the bank BA is formed in the second protective layer PNL2a, a height of a surface curve due to the bank BA may be increased by approximately as much as a thickness of the second protective layer PNL2a. A height h1 of the surface curve due to the bank BA may have a size increased by as much as a thickness dl of the second protective layer PNL2a as compared to a case in which the third opening OP12 is not formed in the second protective layer PNL2a.

The first common organic layer OL1 may be disposed in an area including the first electrode AE, the metal pattern 20a, and the bank BA. The first common organic layer OL1 may be disposed along a surface curve due to the second and fourth openings OP22 and OP21 of the bank BA.

The first common organic layer OL1 may be in contact with the first electrode AE in the fourth opening OP21. The first common organic layer OL1 may be in contact with the metal pattern 20a in the second opening OP22.

When the display apparatus is driven, a ground voltage may be provided to the metal pattern 20a. Accordingly, a leakage current flowing along the first common organic layer OL1 of the first sub-pixel SP1 may be discharged through the metal pattern 20a, thereby preventing the leakage current from flowing to the neighboring second sub-pixel SP2. In addition, a leakage current flowing along the first common organic layer OL1 of the second sub-pixel SP2 may be discharged through the metal pattern 20a, thereby preventing the leakage current from flowing to the neighboring first sub-pixel SP1.

Referring to FIG. 8, a contact hole H2 may be formed by opening a portion of the first protective layer PNL1 below the third opening OP12. A portion of the ground line M1 of the substrate 10 may be exposed through the contact hole H2.

The metal pattern 20a may be disposed on the ground line M1 exposed by the contact hole H2 and a sidewall of the contact hole H2. The metal pattern 20a may be in contact with the ground line M1 in the contact hole H2. The metal pattern 20a may be connected to the ground line M1 through the contact hole H2. The metal pattern 20a may be directly connected to the ground line M1 while being in contact with the ground line M1.

The second opening OP22 of the bank BA may overlap the contact hole H2. The metal pattern 20a disposed on the ground line M1 and the sidewall of the contact hole H2 may be exposed through the second opening OP22 of the bank BA. The first common organic layer OL1 may be in contact with the metal pattern 20a in the contact hole H2.

Although not shown in the drawing, in another example, the second opening OP22 of the bank BA may not overlap the contact hole H2, and the bank BA may be disposed to cover the metal pattern 20a disposed on the ground line M1 and the sidewall of the contact hole H2 and fill the contact hole H2.

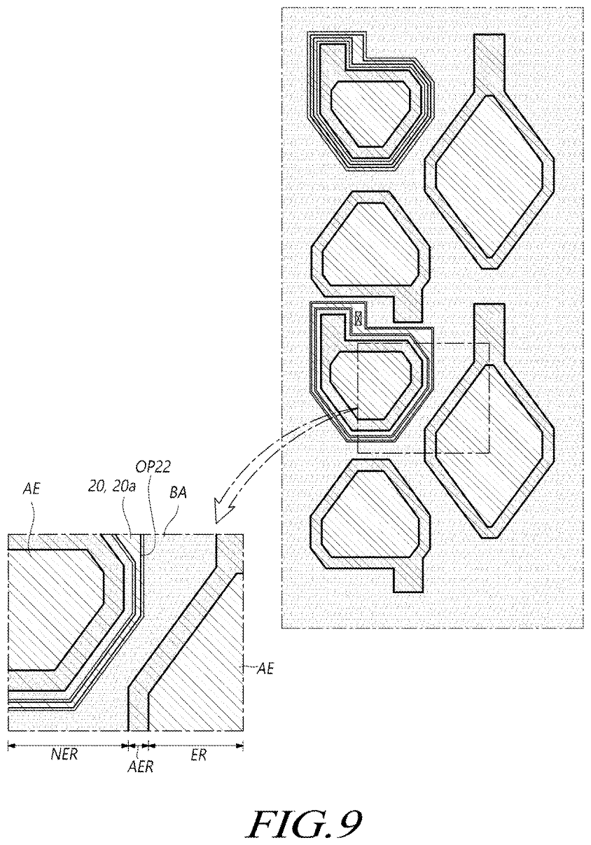

FIG. 9 is a plan view illustrating another example of the display apparatus according to embodiments of the present specification.

The embodiment of FIG. 9 is different from that of FIG. 3 in that there is only a metal pattern 20A and does not include the spacer pattern SP. FIG. 9 includes a second opening OP22 are disposed only on an outer periphery of a portion, e.g., a first electrode AE, of a plurality of first electrodes AE.

Specifically, the metal pattern 20A may disposed only on an outer periphery of one of two adjacent first electrodes AE, and may not be disposed on an outer periphery of the other thereof. The number of metal patterns 20A disposed between adjacent first electrodes AE may be one.

Similar to the metal pattern 20A, the second opening OP22 of a bank BA may also be disposed only on the outer periphery of one of two adjacent first electrodes AE and may not be disposed on the outer periphery of the other thereof. The number of second openings OP22 of the bank BA disposed between adjacent first electrodes AE may be one.

In this case, since the number of the metal pattern 20A and the second opening OP22 disposed between adjacent first electrodes AE is small, a size of an area in which the metal pattern 20A and the second opening OP22 are disposed between adjacent first electrodes AE may be reduced.

In the plan view, the metal pattern 20A may surround an outer side of the first electrode AE in a band shape by being spaced apart therefrom.

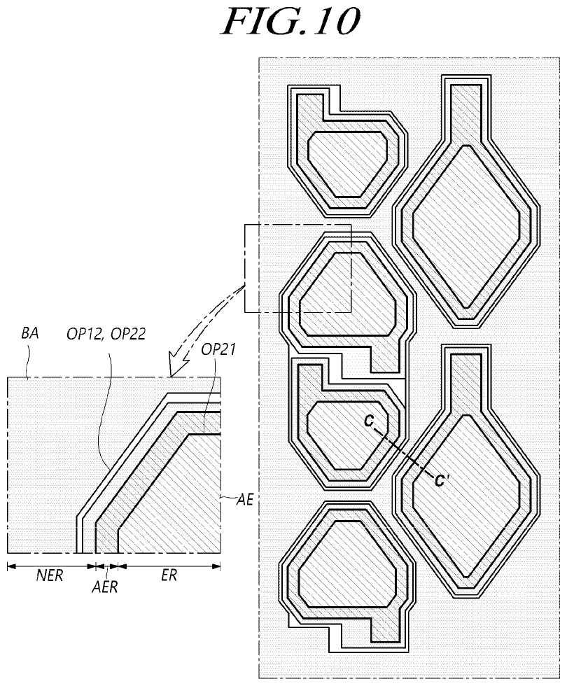

FIG. 10 is a plan view illustrating still another example of the display apparatus according to embodiments of the present specification.

FIG. 10 shows only a first electrode AE, a bank BA, second and fourth openings OP22 and OP21 of the bank BA, and a third opening OP12 of a second protective layer PNL2a among the components of the display apparatus to simplify the drawing. The embodiment of FIG. 10 is different from the embodiment of FIG. 3 in that the metal pattern 20a is not included.

Specifically, an emission area ER of a sub-pixel may be exposed through the fourth opening OP21 of the bank BA. The first electrode AE may be disposed in the emission area ER of the sub-pixel and an additional emission area AER around the emission area ER. In addition, the first electrode AE may be disposed in a non-emission area NER around the additional emission area AER. The bank BA may cover the first electrode AE of the additional emission area AER and the non-emission area NER.

The second opening OP22 may be formed on the bank BA in the non-emission area NER between adjacent sub-pixels. The second opening OP22 of the bank BA may be disposed between adjacent first electrodes AE.

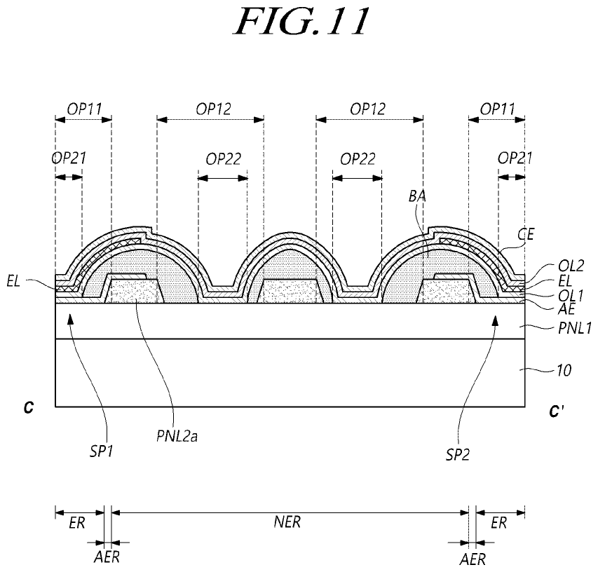

As will be described below with reference to FIG. 11, the third opening OP12 overlapping the second opening OP22 of the bank BA may be formed in a second protective layer PNL2a below the bank BA.

When the third opening OP12 overlapping the second opening OP22 of the bank BA is formed in the second protective layer PNL2a, a height of a surface curve due to the second opening OP22 of the bank BA increases, and accordingly, a length of a first common organic layer OL1 increases in an area between adjacent sub-pixels, and thus a length of a path through which a leakage current flowing along the first common organic layer OL1 of the sub-pixel is transmitted to another adjacent sub-pixel is increased, thereby reducing a side leakage current between adjacent sub-pixels.

The second opening OP22 of the bank BA may be disposed along a contour corresponding a shape of the entire or partial outer periphery of the first electrode AE. The third opening OP12 of the second protective layer PNL2a may be disposed along a contour corresponding the shape of the entire or partial outer periphery of the first electrode AE. Accordingly, a size of an area in which the second opening OP22 of the bank BA and the third opening OP12 of the second protective layer PNL2a are disposed between two adjacent first electrodes AE may be reduced as much as possible.

The third opening OP12 of the second protective layer PNL2a may be disposed, for example, to surround an outer periphery of each of two adjacent first electrodes AE. In this case, two third openings OP12 are formed between two adjacent first electrodes AE to increase the number of surface curves, and a length of the first common organic layer disposed on the surface curves becomes longer, thereby more effectively reducing the side leakage current.

FIG. 11 is a view illustrating an example of a cross section taken along line C-C′ of FIG. 10.

Referring to FIG. 11, a first protective layer PNL1 may be disposed on a substrate 10, and the second protective layer PNL2a may be disposed on a first protective layer PNL1. A portion of the second protective layer PNL2a corresponding to the emission area ER and the additional emission area AER of the sub-pixel may be open to form a first opening OP11. In the emission area ER, a portion of the first protective layer PNL1 may be exposed through the first opening OP11 of the second protective layer PNL2a. In the additional emission area AER, a side surface (an inclined surface) of the second protective layer PNL2a may be exposed through the first opening OP11.

The first electrode AE may be disposed in an area including the first opening OP11 of the second protective layer PNL2a. The first electrode AE may be disposed on the first protective layer PNL1 exposed through the first opening OP11. In addition, the first electrode AE may be disposed on the side surface (the inclined surface) of the second protective layer PNL2a exposed by the first opening OP11. The inclined portion of the first electrode AE disposed on the inclined surface of the second protective layer PNL2a may serve to reflect light generated from the emission layer EL, thereby increasing light extraction efficiency.

The third opening OP12 may be formed on the second protective layer PNL2a in the non-emission area NER between adjacent sub-pixels. A portion of the first protective layer PNL1 may be exposed through the third opening OP12 of the second protective layer PNL2a between adjacent first electrodes AE. The third opening OP12 may be formed together with the first opening OP11 when the first opening OP11 is formed.

The bank BA may be disposed on the second protective layer PNL2a. The bank BA may cover the inclined portion of the first electrode AE.

The bank BA may have a plurality of fourth openings OP21 exposing a plurality of emission areas ER of a plurality of sub-pixels. At least a portion of the first electrode AE disposed on a bottom surface of the first opening OP11 of the second protective layer PNL2a may be exposed through the fourth opening OP21 of the bank BA.

The second opening OP22 may be formed in the bank BA in the non-emission area NER. At least a portion of the first protective layer PNL1 exposed through the third opening OP12 of the second protective layer PNL2a may be exposed through the second opening OP22 of the bank BA. The second opening OP22 of the bank BA may overlap the third opening OP12 of the second protective layer PNL2a. Around the second opening OP22, the bank BA may cover a side surface of the second protective layer PNL2a, which is exposed through the third opening OP12.

As described above, when the third opening OP12 overlapping the second opening OP22 of the bank BA is formed in the second protective layer PNL2a, the height of the surface curve due to the second opening OP22 of the bank BA may be increased by approximately as much as a thickness of the second protective layer PNL2a.

The first common organic layer OL1 may be disposed in an area including the first electrode AE, the metal pattern 20a, and the bank BA. The first common organic layer OL1 may be disposed along a surface curve due to the second opening OP22 of the bank BA and the fourth opening OP21 of the bank BA.

According to the present embodiment, by forming the third opening OP12 overlapping the second opening OP22 of the bank BA in the second protective layer PNL2a in the non-emission area NER between the adjacent first and second sub-pixels SP1 and SP2, a height of a surface curve of the non-emission area NER between the first sub-pixel SP1 and the second sub-pixel SP2 may be increased, and thus a length of the first common organic layer OL1 disposed along the surface curve may be increased, so that a leakage current flowing along the first common organic layer OL1 in one of the first sub-pixel SP1 and the second sub-pixel SP2 may be suppressed from being transmitted to the other thereof.

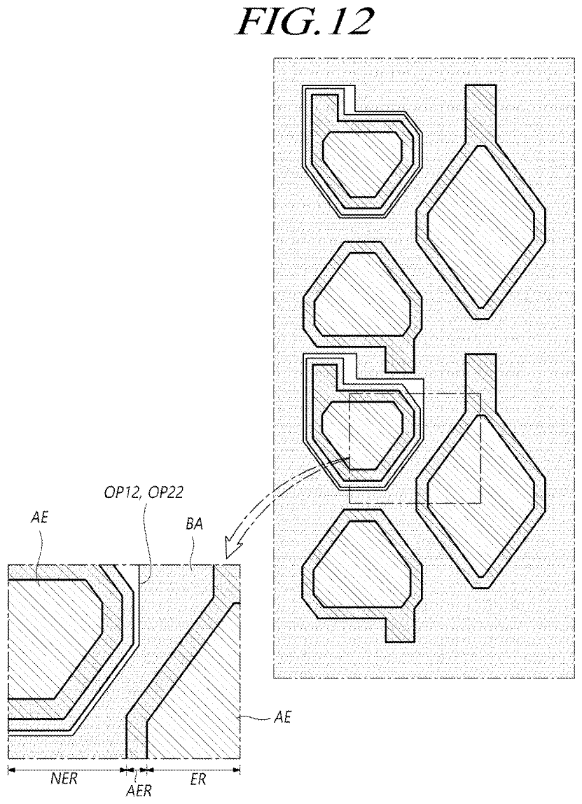

FIG. 12 is a plan view illustrating yet another example of the display apparatus according to embodiments of the present specification.

The embodiment of FIG. 12 is different from that of FIG. 11 in that a second opening OP22 and a third opening OP12 are disposed only on an outer periphery of a portion, e.g., a first electrode AE, of a plurality of first electrodes AE.

Specifically, the second opening OP22 of a bank BA and the third opening OP12 of a second protective layer PNL2a may be disposed only on an outer periphery of one of two adjacent first electrodes AE, and the second opening OP22 of the bank BA and the third opening OP12 of the second protective layer PNL2a may not be disposed on an outer periphery of the other thereof. The number of the second openings OP22 of the bank BA and the third openings OP12 of the second protective layer PNL2a disposed between adjacent first electrodes AE may be one each.

Since the number of the second opening OP22 and the third opening OP12 disposed between adjacent first electrodes AE is small, a size of an area in which the second opening OP22 and the third opening OP12 are disposed between adjacent first electrodes AE may be reduced.

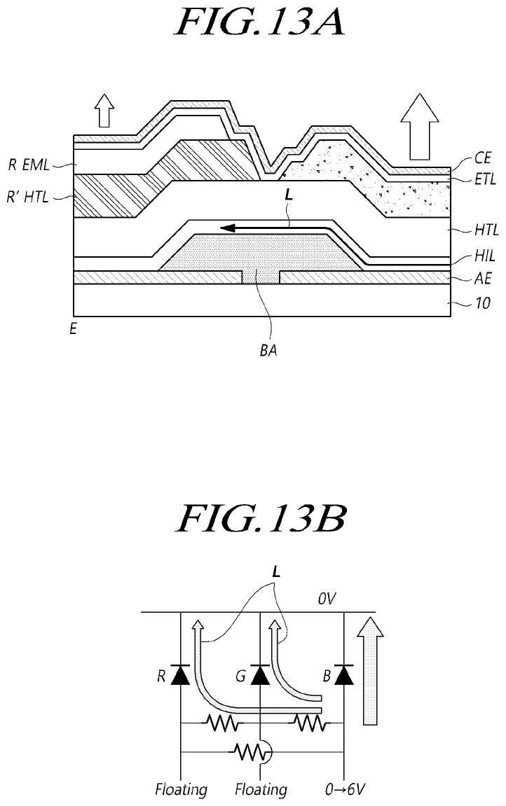

FIG. 13A is a cross-sectional view of a display apparatus according to a comparative example of the present specification.

As one form of an organic light-emitting display apparatus, in order to simplify the drawing, the configuration of the display apparatus is simply illustrated as shown in FIG. 13A by omitting other components. A first electrode AE, a bank BA, a hole injection layer HIL, and a hole transport layer HTL are sequentially formed on a substrate 10, and emission layers R EML (red emission layer) and B EML (blue emission layer), an electron transport layer ETL, and a second electrode CE may be sequentially formed above the first electrode AE, the bank BA, the hole injection layer HIL, and the hole transport layer HTL.

For example, in a red sub-pixel, in order to match a light emission height, an auxiliary hole transport layer R′ HTL may be further provided between the hole transport layer HTL and a red emission layer R EML.

The first electrode AE, which is a first electrode of each light-emitting element, may be independently controlled. Accordingly, the light-emitting element may be independently controlled. This enables each sub-pixel to generate an independently controlled amount of light.

The organic layers excluding the emission layer EL are continuously formed in common in a plurality of sub-pixels without a shadow mask. The hole injection layer HIL and the hole transport layer HTL, which are common organic layers, have an inherent resistance component. A resistance of each of the hole injection layer HIL and the hole transport layer HTL decreases as a hole mobility of each of the hole injection layer HIL and the hole transport layer HTL increases. When the resistance of each of the hole injection layer HIL and the hole transport layer HTL decreases as the hole mobility thereof increases, a side leakage current increases.

Due to the side leakage current, as shown in FIG. 13B, a phenomenon in which even a light-emitting element G of a green sub-pixel and a light-emitting element R of a red sub-pixel are turned on even when only a light-emitting element B of a blue sub-pixel is driven and the light-emitting element G of the green sub-pixel and the light-emitting element R of the red sub-pixel are not driven may occur.

Although a voltage is applied between the first electrode AE and the second electrode CE of the blue sub-pixel in order to emit pure blue light, a phenomenon in which the light-emitting element R of the red sub-pixel and the light-emitting element G of the green sub-pixel are turned on due to a side leakage current L flowing along the common organic layer occurs.

When such unintended sub-pixel emits light, a color reproduction range is reduced, and in particular, spots or color abnormalities may be visually recognized when images of low gray scales are displayed.

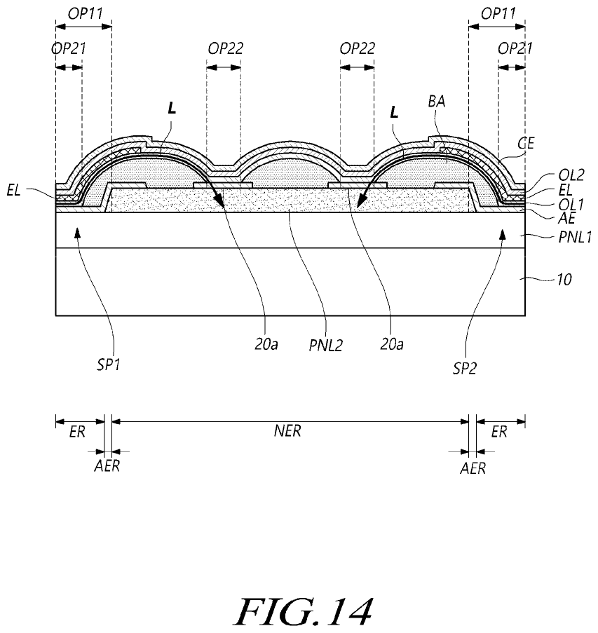

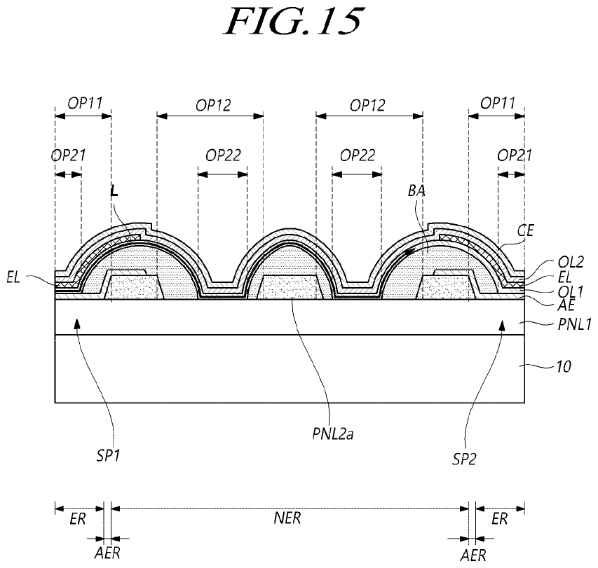

FIGS. 14 and 15 are views illustrating effects of embodiments of the present specification in contrast to the embodiment of FIG. 13A and FIG. 13B.

As shown in FIG. 14, in the embodiments of the present specification, the metal pattern 20A is disposed between the first electrodes AE of adjacent sub-pixels SP1 and SP2, and a ground voltage is supplied to the metal pattern 20A when the display apparatus is driven, so that a current flowing along the first common organic layer OL1 is discharged through the metal pattern 20A, thereby reducing a side leakage current between adjacent sub-pixels SP1 and SP2.

As shown in FIG. 15, in the examples of the present specification, the third opening OP12 overlapping the second opening OP22 of the bank BA is disposed in the second protective layer PNL2a in the non-emission area NER between adjacent sub-pixels SP1 and SP2 to increase the height of the surface curve due to the second opening OP22 of the bank BA, so that the length of the first common organic layer OL1 may be increased in an area between the adjacent sub-pixels SP1 and SP2, and thus the length of the path through which the leakage current flowing along the first common organic layer OL1 from one of the adjacent sub-pixels SP1 and SP2 is transmitted to the other thereof is increased, thereby reducing the side leakage current between adjacent sub-pixels SP1 and SP2.

FIG. 16 is an exemplary cross-sectional view of a display panel according to embodiments of the present specification.

Referring to FIG. 16, a multi-buffer layer MBUF, a metal layer BSM, an active buffer layer ABUF, a transistor, and a capacitor may be disposed between a substrate 10 and a first protective layer PNL1.

The multi-buffer layer MBUF may be disposed on the substrate 10, and the metal layer BSM may be disposed on the multi-buffer layer MBUF. The metal layer BSM may be a light shield layer that shields light.

The active buffer layer ABUF may be disposed on the metal layer BSM. An active layer ACT of the transistor may be disposed on the active buffer layer ABUF. A gate insulating film GI may be disposed to cover the active layer ACT.

A gate electrode GATE of the transistor may be disposed on the gate insulating film GI. A first interlayer insulating film ILD1 may be disposed to cover the gate electrode GATE. A second interlayer insulating film ILD2 may be disposed on the first interlayer insulating film ILD1.

Two source-drain electrodes SD may be disposed on the second interlayer insulating film ILD2. One of the two source-drain electrodes SD is a source node of the transistor and the other thereof is a drain node of the transistor.

The two source-drain electrodes SD may be electrically connected to one side and the other side of the active layer ACT through contact holes of the second interlayer insulating film ILD2, the first interlayer insulating film ILD1, and the gate insulating film GI, respectively.

A portion of the active layer ACT overlapping the gate electrode GATE is a channel area. One of the two source-drain electrodes SD may be connected to one side of the channel area in the active layer ACT, and the other of the two source-drain electrodes SD may be connected to the other side of the channel area in the active layer ACT.

A ground line M1 may be located on the second interlayer insulating film ILD2. The ground line M1 may be disposed on the same layer as the two source-drain electrodes SD.

The ground line M1 may include the same material as the source-drain electrode SD.

The capacitors may be located on the active buffer layer ABUF. A first capacitor electrode C1 may be located on the active buffer layer ABUF. Alternatively, the first capacitor electrode C1 may be disposed on the same layer as the gate electrode GATE.

A second capacitor electrode C2 may be located on the first interlayer insulating film ILD1. Alternatively, the second capacitor electrode C2 may be disposed on the same layer as the two source-drain electrodes SD.

The second protective layer PNL2 may be disposed on the first protective layer PNL1. A portion of the second protective layer PNL2 corresponding to an emission area and an additional emission area of a sub-pixel may be open to form a first opening OP11. In the emission area, at least a portion of the first protective layer PNL1 may be exposed by the first opening OP11 of the second protective layer PNL2. In the additional emission area, a side surface (an inclined surface) of the second protective layer PNL2 may be exposed by the first opening OP11.

A first electrode AE may be disposed on the first protective layer PNL1 and the second protective layer PNL2. The first electrode AE may be an anode of a light-emitting element. The first electrode AE may be disposed in an area including the first protective layer PNL1 and the side surface (the inclined surface) of the second protective layer PNL2 exposed through the first opening OP11 of the second protective layer PNL2. The first electrode AE may include an inclined portion disposed on the side surface (the inclined surface) of the second protective layer PNL2. A metal pattern 20A may be disposed on the second protective layer PNL2 in the non-emission area NER.

A bank BA may be disposed to cover the second protective layer PNL2. The bank BA may cover the inclined portion of the first electrode AE. The bank BA may include a fourth opening OP21 corresponding to the emission area ER. At least a portion of the first electrode AE disposed on the bottom surface of the first opening OP11 of the second protective layer PNL2 may be exposed through the fourth opening OP21 of the bank BA.

At the emission area ER, EA various emission regions are formed. On each side of the opening OP11 is a non-emission area NER. The pattern structure 20, both the metal pattern (if included) and the spacer are in the NER. In this embodiment, the metal pattern 20a is shown on an opposite side of the opening OP11 from the spacer SP. Within the opening OP11 are a first and second additional emission area AER, which are directly adjacent to the non-emission areas NER on the first and second side of the opening OP11. It is noted that the first and second additional emission are first and second sides of a circular or round additional emission area AER. Immediately adjacent to the additional emission area AER is an additional non-emission area ANER, which is around or encircles the emission area ER.

A second opening OP22 may be formed in the bank BA in the non-emission area. At least a portion of the metal pattern 20A may be exposed through the second opening OP22 of the bank BA.

The metal pattern 20A may be disposed as a stair-shaped step on the first protective layer PNL1 and the second protective layer PNL2.

A first common organic layer OL1 may be disposed on the first electrode AE, the metal pattern 20A, and the second protective layer PNL2. The first common organic layer OL1 may be disposed along a surface curve of the second and fourth openings OP22 and OP21 of the bank BA.

An emission layer EL may be disposed on a portion of the first common organic layer OL1. The emission layer EL may be disposed in an area including the first opening OP11 of the second protective layer PNL2. A second common organic layer OL2 may be disposed on the emission layer EL and the first common organic layer OL1.

For color display, the emission layer EL may be separately formed for each of a red sub-pixel Red SP, a green sub-pixel Green SP, and a blue sub-pixel Blue SP by using a shadow mask. The first common organic layer OL1 may include a hole injection layer HIL and/or a hole transport layer HTL. The second common organic layer OL2 may include an electron transport layer ETL and/or an electron injection layer EIL. The first and second common organic layers OL1 and OL2 may be continuously formed in common in a plurality of sub-pixels without a shadow mask.

The first common organic layer OL1 may be in contact with the first electrode AE in the fourth opening OP21 of the bank BA. In the fourth opening OP21 of the bank BA, the light-emitting element ED may be formed by the first electrode AE, the first common organic layer OL1, the emission layer EL, the second common organic layer OL2, and a second electrode CE. The light-emitting element ED may have a single-layer structure or a multi-layer structure, and the embodiments of the present specification are not limited thereto.

The first common organic layer OL1 may be in contact with the metal pattern 20A in the second opening OP22 of the bank BA. A ground voltage may be supplied to the metal pattern 20A through the ground line M1 when the display apparatus is driven. As the ground voltage is supplied to the metal pattern 20A, a leakage current flowing along the first common organic layer OL1 is discharged through the metal pattern 20A, thereby reducing a leakage current flowing between the sub-pixels.

FIG. 16 includes the spacer pattern or structure SP, which is spaced from the metal pattern 20A by the light-emitting element ED. FIG. 16 includes the pattern structure 20, both the metal pattern 20A and the spacer pattern SP. The spacer pattern SP is positioned on the bank BA, overlapping an end 103 of the metal or light shield layer BSM.

The spacer pattern SP also overlaps a trench 105 that extends down to the active layer ACT. The source-drain electrodes SD interacts with the trench 105, which contacts an end 107, of the active layer ACT. The spacer pattern SP overlaps at least a portion of the trench 105. In some embodiments, the spacer pattern SP is further from the light-emitting element ED than the end 107. The spacer structure SP is in the non-emission regions NER that is on a first side of the light-emitting element ED and the metal pattern 20A is on a second side of the light-emitting element ED.

The second electrode CE may be disposed on the second common organic layer OL2. The second electrode CE may be a cathode of the light-emitting element ED. The second electrode CE extends and overlaps the spacer pattern SP.

An encapsulation layer EN may be disposed on the second electrode CE.

The encapsulation layer EN may have a single-layer structure or a multi-layer structure. For example, as shown in FIG. 16, the encapsulation layer EN may include a first encapsulation layer P1, a second encapsulation layer P2, and a third encapsulation layer P3. The embodiments of the present specification are not limited thereto.

For example, the first encapsulation layer P1 and the third encapsulation layer P3 may be inorganic films, and the second encapsulation layer P2 may be an organic film. Among the first encapsulation layer P1, the second encapsulation layer P2, and the third encapsulation layer P3, the second encapsulation layer P2 is the largest in thickness, and may serve as a planarization layer.

The first encapsulation layer P1 may be disposed on the second electrode CE and may be disposed closest to the light-emitting element ED. The first encapsulation layer P1 may be formed of an inorganic insulating material that is capable of being deposited at a low temperature. For example, the first encapsulation layer P1 may be silicon nitride (SiNx), silicon oxide (SiOx), silicon oxynitride (SiON), aluminum oxide (Al₂O₃), or the like. Since the first encapsulation layer P1 is deposited in a low-temperature atmosphere, the first encapsulation layer P1 can prevent the emission layer EL including an organic material vulnerable to a high-temperature atmosphere from being damaged during deposition processing.

The second encapsulation layer P2 may be formed in an area smaller than that of the first encapsulation layer P1. In this case, the second encapsulation layer P2 may be formed to expose both terminating ends of the first encapsulation layer P1. The second encapsulation layer P2 may serve as a buffer for mitigating stress between respective layers caused by bending of the display apparatus, and serve to enhance planarization performance. For example, the second encapsulation layer P2 may be an acrylic resin, an epoxy resin, polyimide, polyethylene, silicon oxycarbon (SiOC), or the like, and may be formed of an organic insulating material. For example, the second encapsulation layer P2 may be formed by an inkjet method.

The third encapsulation layer P3 may be formed on the substrate SUB on which the second encapsulation layer P2 is formed to cover an upper surface and a side surface of each of the second encapsulation layer P2 and the first encapsulation layer P1. The third encapsulation layer P3 may minimize or prevent external moisture or oxygen from penetrating into the first and second encapsulation layers P1 and P2. For example, the third encapsulation layer P3 is formed of an inorganic insulating material, such as silicon nitride (SiNx), silicon oxide (SiOx), silicon oxynitride (SiON), aluminum oxide (Al₂O₃), or the like.

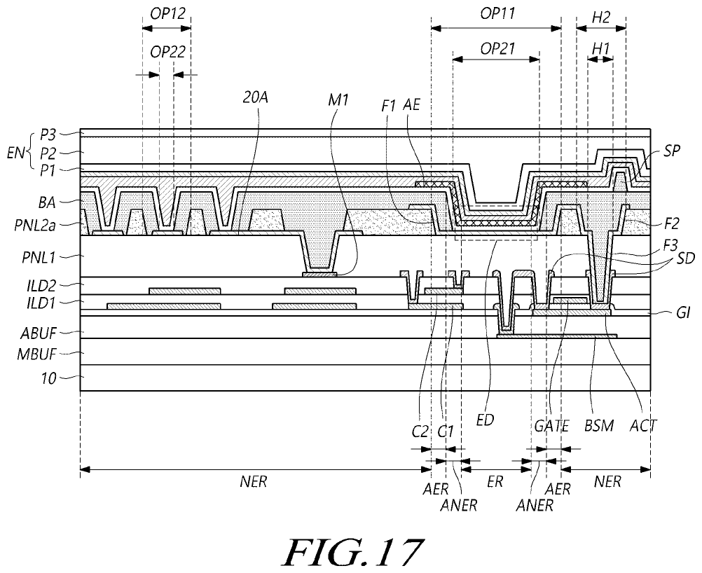

FIG. 17 is a cross-sectional view illustrating another example of the display panel according to the present embodiments.

The display apparatus of FIG. 17 is different from the display apparatus of FIG. 16 in that a third opening OP12 is additionally formed in a second protective layer PNL2a, and a metal pattern 20A is disposed on a first protective layer PNL1. Hereinafter, a duplicated description of the same part will be omitted for simplicity of description.

In a non-emission area, the third opening OP12 may be formed in the second protective layer PNL2a. In the non-emission area, a portion of the first protective layer PNL1 may be exposed through the third opening OP12 of the second protective layer PNL2a.

At least a portion of the metal pattern 20A may be disposed on the first protective layer PNL1 exposed through the third opening OP12 of the second protective layer PNL2a.

A bank BA may be disposed on the second protective layer PNL2a. The bank BA may cover a side surface (an inclined surface) of the second protective layer PNL2a exposed through the third opening OP12. The bank BA may include a second opening OP22 exposing the metal pattern 20A. The second opening OP22 of the bank BA may overlap the third opening OP12 of the second protective layer PNL2a.

When the third opening OP12 overlapping the second opening OP22 of the bank BA is additionally formed in the second protective layer PNL2a as described above, a height of a surface curve may be increased by approximately as much as a thickness of the second protective layer PNL2a. For example, by additionally forming the third opening OP12 in the second protective layer PNL2a, the height of the surface curve may be increased without increasing a thickness of the bank BA.

Accordingly, a length of a first common organic layer OL1 disposed along the surface curve increases, so that a leakage current flowing through the first common organic layer OL1 may be reduced from being transmitted to an adjacent sub-pixel.

In FIG. 17, the metal pattern 20A may be omitted. Although the metal pattern 20A is omitted and does not discharge the leakage current, as described above, when the surface curve is increased and the first common organic layer OL1 is disposed thereon to increase the length of a leakage current transmission path by the first common organic layer OL1, an effect of reducing a side leakage current between adjacent sub-pixels is achievable.

FIG. 17 includes the substrate 10, which may be a polyimide substrate. A multi-buffer layer MBUF is on the substrate 10. Various patterns ACT, SD, and GATE, various insulating films MBUF, ABUF, GI, ILD1, ILD2 and a various metal patterns for forming transistors, such as thin-film transistors, are on the substrate 11. A metal layer BSM is on the multi-buffer layer MBUF. The metal layer BSM may be a light shield layer that blocks (or shields) light.

An active buffer layer ABUF may be disposed on the metal layer BSM. An active layer ACT of the transistor may be disposed on the active buffer layer ABUF. A gate insulating film GI may be disposed to cover the active layer ACT. A gate electrode GATE of the transistor may be disposed on the gate insulating film GI. A first interlayer insulating film ILD1 may be disposed to cover the gate electrode GATE. A second interlayer insulating film ILD2 may be disposed on the first interlayer insulating film ILD1.

Two connection electrodes SD may be disposed on the second interlayer insulating film ILD2. One of the two connection electrodes SD is a source node of the transistor and the other thereof is a drain node of the transistor.

The two connection electrodes SD may be electrically connected to one side and the other side of the active layer ACT through contact holes pass through the second interlayer insulating film ILD2, the first interlayer insulating film ILD1, and the gate insulating film GI, respectively.

A portion of the active layer ACT overlapping the gate electrode GATE is a channel area. One of the two connection electrodes SD may be connected to one side of the channel area in the active layer ACT, and the other of the two connection electrodes SD may be connected to the other side of the channel area in the active layer ACT.

The transistor may at least partially overlap the light-emitting element. The display apparatus according to embodiments of the present specification includes a top emission organic electric element, and at least a portion of the transistor may overlap the light-emitting element.

A capacitor may be located above the active buffer layer ABUF. A first capacitor electrode C1 may be located above the active buffer layer ABUF. Alternatively, the first capacitor electrode C1 may be disposed on the same layer as the gate electrode GATE. In some embodiments, the first capacitor electrode C1 is on the same layer as the gate electrode GATE of the transistor shown in FIG. 17. In some embodiments, the first capacitor electrode C1 includes the same material as the gate electrode GATE of the transistor. In some embodiments, the first capacitor electrode C1 and the gate electrode GATE of the transistor is formed during the same manufacturing process.

A second capacitor electrode C2 may be located on the first interlayer insulating film ILD1. Alternatively, the second capacitor electrode C2 may be disposed on the same layer as the connection electrode SD.

A first protective layer PNL1 may be disposed to cover the connection electrode SD. A portion of the first protective layer PNL1 may be open to form the first contact hole H1. One of the connection electrodes SD may be exposed by the first contact hole H1.

A second protective layer PNL2a may be disposed on the first protective layer PNL1. A portion of the second protective layer PNL2a corresponding to the emission area EA of the sub-pixel may be open to form the first opening OP11. At least a portion of the first protective layer PNL1 may be exposed by the first opening OP11. The first inclined surface F1 of the second protective layer PNL2a may be exposed by the first opening OP11.

A portion of the second protective layer PNL2a may be open to form the second contact hole H2. The first contact hole H1 and the first protective layer PNL1 around the first contact hole H1 may be exposed by the second contact hole H2. A second inclined surface F2 of the second protective layer PNL2a may be exposed by the second contact hole H2. A bottom portion of the second contact hole H2 may have a dimension larger than that of a top portion of the first contact hole H1.

The first electrode AE may be disposed in an area including the first opening OP1 of the second protective layer 13 and the first and second contact holes H1 and H2. The first electrode AE may be an anode.

The first electrode AE may be disposed on the upper surface of the first protective layer PNL1 and the first inclined surface F1 of the second protective layer PNL2a, which are exposed through the first opening OP11. In addition, the first electrode AE may be disposed on the second inclined surface F2 of the second protective layer PNL2a exposed through the second contact hole H2. The first electrode AE may be continuously disposed along the first inclined surface F1 of the second protective layer PNL2a, an upper surface of the second protective layer PNL2a connected to the first inclined surface F1, and the second inclined surface F2 of the second protective layer PNL2a connected to the upper surface of the second protective layer PNL2a.

In addition, the first electrode AE may be disposed along the third inclined surface F3 of the first protective layer PNL1 exposed through the first contact hole H1. The first electrode AE may be continuously disposed along the second inclined surface F2 of the second protective layer PNL2a, the upper surface of the first protective layer PNL1 connected to the second inclined surface F2, and the third inclined surface F3 of the first protective layer PNL1 connected to the upper surface of the first protective layer PNL1.

In addition, the first electrode AE may be disposed on the connection electrode SD exposed through the first contact hole H1, and may be directly connected to the connection electrode SD.

A bank BA may be disposed to cover a portion of the first electrode AE. The bank BA may be disposed on the upper surface of the second protective layer PNL2a and an edge of the first opening OP1 of the second protective layer PNL2a. The bank BA may be disposed to fill the first and second contact holes H1 and H2. A spacer SP may be disposed on the bank BA in an area between adjacent sub-pixels. The bank BA is formed on portions of the pattern structure 20, including on portions of the metal pattern 20A. The spacer SP may be on the BA. The spacer SP may be formed by the same material as the bank or as part of the bank.

The bank BK may include one or more materials of an inorganic insulating material such as SiNx or SiOx and an organic insulating material such as benzocyclobutene (BCB), acryl resin, epoxy resin, phenolic resin, polyamide resin, or polyimide resin, but embodiments of the present disclosure are not limited thereto. As another example, the bank BK may include a black bank to which a black pigment is added, so as to reduce the reflection of light, but embodiments of the present disclosure are not limited thereto.

At least a portion of the first electrode AE disposed on a bottom surface of the first opening OP11 may be exposed by the bank BA. A first common organic layer OL1 is on a side surface of the bank BA and an opening of the bank BA. In the opening of the bank BA, the emission layer EL may be in contact with the first common organic layer OL1. A second common organic layer OL2 is on the emission layer EL. A second electrode CE may be disposed on the second common organic layer OL2. The second electrode CE may be a cathode of the light-emitting element.

A first functional layer and a second functional layer may be selectively disposed below and above the emission layer EL. The first functional layer may include a hole injection layer (HIL) and/or a hole transport layer (HTL), and the second functional layer may include an electron transport layer (ETL) and/or an electron injection layer (EIL).

The first functional layer and the second functional layer disposed below and above the emission layer EL may be integrally formed throughout the substrate 10 to cover a plurality of sub-pixels disposed in the display area using an open mask.

An encapsulation layer EN may be disposed on the second electrode CE. The encapsulation layer EN may have a single-layer structure or a multi-layer structure. For example, as shown in FIG. 17, the encapsulation layer EN may include a first encapsulation layer P1, a second encapsulation layer P2, and a third encapsulation layer P3.

For example, the first encapsulation layer P1 and the third encapsulation layer P3 may be inorganic films, and the second encapsulation layer P2 may be an organic film. Among the first encapsulation layer P1, the second encapsulation layer P2, and the third encapsulation layer P3, the second encapsulation layer P2 is the largest in thickness, and may serve as a planarization layer.

The first encapsulation layer P1 may be disposed on the second electrode CE and may be disposed closest to the light-emitting element ED. The first encapsulation layer P1 may be formed of an inorganic insulating material that is capable of being deposited at a low temperature. For example, the first encapsulation layer P1 may be silicon nitride (SiNx), silicon oxide (SiOx), silicon oxynitride (SiON), aluminum oxide (Al₂O₃), or the like. Since the first encapsulation layer P1 is deposited in a low-temperature atmosphere, the first encapsulation layer P1 can prevent the emission layer EL including an organic material vulnerable to a high-temperature atmosphere from being damaged during deposition processing.

The second encapsulation layer P2 may be formed in an area smaller than that of the first encapsulation layer P1. In this case, the second encapsulation layer P2 may be formed to expose both terminating ends of the first encapsulation layer P1. The second encapsulation layer P2 may serve as a buffer for mitigating stress between respective layers caused by bending of the display apparatus, and serve to enhance planarization performance. For example, the second encapsulation layer P2 may be an acrylic resin, an epoxy resin, polyimide, polyethylene, silicon oxycarbon (SiOC), or the like, and may be formed of an organic insulating material. For example, the second encapsulation layer P2 may be formed by an inkjet method.

An emission area includes an emission part ER and an additional emission part AER. The emission part ER overlaps with the light-emitting element from a plan view. A non-emission arca includes a non-emission part NER and an additional non-emission part ANER. The additional non-emission part ANER is between the emission part ER and the additional emission part AER from a plan view. The non-emission part NER is located outside of the additional emission part AER from a plan view.

At least one side of the additional non-emission part ANER overlaps a middle portion of the metal layer BSM. In some embodiments, the metal layer BSM at least partially overlaps the additional emission part AER from a plan view. The additional emission part also overlaps a portion of the gate and the metal layer BSM.

The spacer SP is spaced from an outer boundary of the additional emission area AER. The spacer SP may be aligned with a center line of the trench 105. As shown, the spacer SP may be shifted from the center line, while still overlapping the trench 105.

In some embodiments, the emission part ER is surrounded by the additional non-emission part ANER from a plan view, In some embodiments, the additional non-emission part ANER is surrounded by the additional emission part AER from a plan view. In some embodiments, the additional emission part AER is surrounded by the non-emission area NER from a plan view.

The spacer SP is spaced from the outer boundary of the additional emission area AER along a first direction (left to right in FIG. 17) by a distance that is greater than a width along the first direction of the additional emission area AER, i.e. on side of the AER. The spacer may be spaced from the outer boundary of the additional emission area AER along the first direction by a distance that is less than a dimension of opening OP21 along the first direction.

In FIG. 17, the spacer SP is aligned with the angled surface F2, which is between a boundary of hole H1 and another hold H2, which are aligned with one of the source-drains. This pattern structure 20, in the non-emission regions between sub-pixels can include features on an associated with the bank. Some embodiments include the metal pattern 20a and the spacer SP, these are conductive and insulative portions of the pattern.

The pattern structure is in conduction with a first common organic layer that is on the first electrode AE. The emission layer EL is on the first electrode AE. The pattern structure is on the left and right side of the emission layer, along the first direction of FIG. 17.

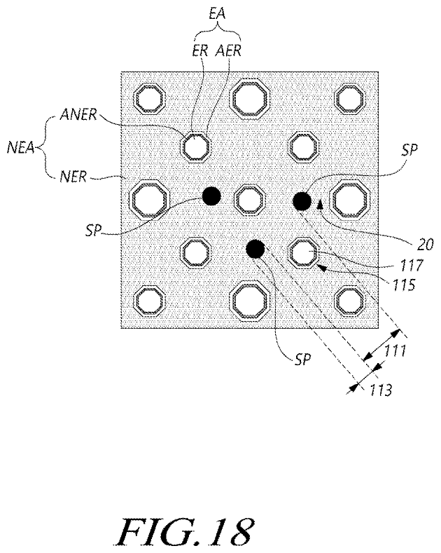

FIG. 18 is a plan view illustrating emission parts and a non-emission part of a display apparatus according to embodiments of the present disclosure.

Referring to FIG. 18, a plurality of emission parts EA may be disposed in a display area to correspond to a plurality of sub-pixels. An area other than the plurality of emission parts EA may correspond to a non-emission part NEA. Areas of the emission parts of at least two sub-pixels may be different from each other, but the present specification is not limited thereto.

At least one emission part EA disposed in the display area may include a plurality of emission areas ER and AER. For example, one emission part EA may include an emission area ER and an additional emission area AER surrounding the emission area ER.

The non-emission part NEA may include a non-emission area NER and an additional non-emission area ANER.

The additional non-emission area ANER may be disposed between the emission area ER and the additional emission area AER. For example, the emission area ER and the additional emission area AER may be distinguished through the additional non-emission area ANER. The additional non-emission area ANER may be smaller in area than the emission area ER.

The additional non-emission area ANER may be in a black state when the display apparatus is in an on state, or the additional non-emission area ANER may have a lower luminance than the emission area ER and the additional emission area AER due to light incident from at least one of the emission area ER and the additional emission area AER.

The non-emission area NER may be disposed between the plurality of emission parts EA. For example, neighboring emission parts EA may be distinguished through the non-emission arca NER.

The emission area ER may have an elliptical shape in a plan view. The additional non-emission area ANER and the additional emission area AER may be formed in an elliptical ring shape around the elliptical emission area ER. However, the embodiments of the present specification are not limited thereto, and the emission area ER may have a circular shape, an elliptical shape, or a polygonal shape, for example, a triangular shape, a quadrangular shape, an octagonal shape, or the like in a plan view, and a combination thereof is also possible. The shape of each of the additional non-emission area ANER and the additional emission area AER may vary according to the shape of the emission area ER.

FIG. 18 includes a plurality of spacers SP, which are positioned between adjacent ones of the sub-pixels. A distance 111 between a first spacer and a second spacer is greater than a distance or diameter 117 of an additional emission area AER of a closest sub-pixel 115.

The plurality of sub-pixels include a plurality of sizes of sub-pixels. A distance 111 between adjacent, i.e. a closest spacer to a respective spacer, is greater than a largest diameter 117 of an adjacent pixel to the respective spacer. A diameter 113 of the spacers is less than the smallest diameter 117 of the sub-pixels.

The pattern 20 may be a consistent cadence or sequence around each pixel. Alternatively, the pattern's 20 sub-components, conductive, insulative, or a combination of both, may be an irregular pattern where spaces between sub-components are not consistent.

The display panel according to the embodiments of the present specification described above may be briefly described as follows.

A display apparatus according to embodiments of the present specification may include a first protective layer disposed on a substrate, a second protective layer disposed on the first protective layer and having a plurality of first openings, a plurality of first electrodes disposed on the plurality of first openings, a bank disposed on the second protective layer and having a second opening in an area between two adjacent first electrodes among the plurality of first electrodes, a metal pattern disposed below the second opening, and a common organic layer disposed in an area including the plurality of first electrodes, the bank, and the metal pattern and connected to the plurality of first electrodes and the metal pattern.

According to embodiments of the present specification, a leakage current of the common organic layer may be discharged through the metal pattern.

According to embodiments of the present specification, a ground voltage may be applied to the metal pattern.

According to embodiments of the present specification, at least a portion of the metal pattern may be disposed on the second protective layer exposed by the second opening of the bank.

According to embodiments of the present specification, the metal pattern may be connected to a ground line of the substrate through a contact hole passing through the first and second protective layers and exposing the ground line.

According to embodiments of the present specification, the ground line may be located on the same layer as a source-drain electrode.

According to embodiments of the present specification, the ground line may include the same material as a source-drain electrode.

According to embodiments of the present specification, the second protective layer may further include a third opening overlapping the second opening, and at least a portion of the metal pattern may be disposed on the first protective layer exposed by the third opening.

According to embodiments of the present specification, the bank may cover an inclined surface of the second protective layer exposed by the third opening.

According to embodiments of the present specification, the metal pattern may be connected to the ground line of the substrate through a contact hole passing through the first protective layer and exposing the ground line.

According to embodiments of the present specification, the metal pattern may be disposed along a contour corresponding to a shape of the entire or partial outer periphery of at least one of the plurality of first electrodes.

According to embodiments of the present specification, the metal pattern may be disposed on an outer periphery of each of two adjacent first electrodes among the plurality of first electrodes.

According to embodiments of the present specification, the metal pattern may be disposed on an outer periphery of one of two adjacent first electrodes among the plurality of first electrodes, and may not be disposed on an outer periphery of the other thereof.

According to embodiments of the present specification, the metal pattern may be located on the same layer as the first electrode.

According to embodiments of the present specification, the metal pattern may include the same material as the first electrode.

According to embodiments of the present specification, the metal pattern may surround the first electrode while being spaced apart from an outside of the first electrode.

According to embodiments of the present specification, the metal pattern may be disposed as a stair-shaped step on the first protective layer and the second protective layer.

A display apparatus according to embodiments of the present specification may include a first protective layer disposed on a substrate, a second protective layer located on the first protective layer and having a plurality of first openings and a second opening, a plurality of first electrodes disposed on the plurality of first openings, a bank covering the second protective layer and having a plurality of third openings exposing the plurality of first electrodes and a fourth opening overlapping the second opening, and a common organic layer disposed in an area including the plurality of first electrodes and the bank and disposed along a surface curve of the plurality of third openings and the fourth opening.

According to embodiments of the present specification, the bank around the fourth opening may cover an inclined surface of the second protective layer exposed through the second opening.

According to embodiments of the present specification, the second opening may be disposed along a contour corresponding to a shape of the entire or partial outer periphery of at least one of the plurality of first electrodes.

According to embodiments of the present specification, the second opening may be disposed on an outer periphery of each of two adjacent first electrodes among the plurality of first electrodes.

According to embodiments of the present specification, the second opening may be disposed on an outer periphery of one of two neighboring first electrodes among the plurality of first electrodes, and may not be disposed on an outer periphery of the other thereof.

According to embodiments of the present specification, each of the plurality of first electrodes may include an inclined portion disposed on an inclined surface of the second protective layer exposed by the first opening and configured to reflect light.

Through such a structure, according to embodiments of the present specification, there is an effect of providing a display apparatus capable of reducing a side leakage current by allowing a current flowing through a common organic layer to be discharged through a metal pattern by forming an opening in a bank between adjacent sub-pixels, arranging the metal pattern below the opening of the bank, and applying a ground voltage to the metal pattern.

According to embodiments of the present specification, there is an effect of providing a display apparatus capable of reducing a side leakage current by increasing a length of a path through which a leakage current flows by forming an opening in a second protective layer below a bank between adjacent sub-pixels, and forming an opening overlapping the opening of the second protective layer in the bank to make the surface irregularities large and disposing a common organic layer thereon.

According to embodiments of the present specification, there is an effect of providing a display apparatus capable of improving a color reproduction rate by reducing a side leakage current and thus minimizing an unintended light-emitting element from emitting light, and improving display quality by minimizing spots or color abnormalities from being visually recognized when an image of a low gray scale is displayed.

The above description has been presented to enable any person skilled in the art to make and use the technical idea of the present disclosure, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the present disclosure. The above description and the accompanying drawings provide an example of the technical idea of the present disclosure for illustrative purposes only. That is, the disclosed embodiments are intended to illustrate the scope of the technical idea of the present disclosure.

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A device, comprising:
a first pixel having:
a first emission area;
a second emission area surrounds the first emission area;
a first non-emission area between the first emission area and the second emission area, the first non-emission area surrounds the first emission area;
a second non-emission area around the pixel, the first non-emission area spaced from the second non-emission area by the second emission area, the second non-emission area including:
a pattern that includes a first portion spaced from the second portion by a distance;
a second pixel spaced from the first pixel by the second non-emission area.

2. The device of claim 1 wherein the first portion of the pattern is a spacer and the second portion of the pattern is a metal pattern.

3. The device of claim 1, comprising: a first protective layer;
a second protective layer on the first protective layer;
a plurality of first electrodes;
a bank on the second protective layer;
a common organic layer in an area including the plurality of first electrodes and the bank, the common organic layer being connected to the plurality of first electrodes.

4. The device of claim 3 wherein the first portion of the pattern is a spacer that is on the bank.

5. The device of claim 3 wherein the second protective layer having a plurality of first openings, the plurality of first electrodes being on the plurality of first openings, the bank having a second opening in an area between two adjacent first electrodes among the plurality of first electrode, the first and second portions of the pattern being a metal pattern.

6. The device of claim 5 wherein the common organic layer is on the metal pattern.

7. The device of claim 6, wherein the metal pattern is connected to a ground line through a contact hole passing through the first and second protective layers that exposes the ground line.

8. The device of claim 7, wherein
the second protective layer includes a third opening overlapping the second opening, and
at least a portion of the metal pattern is on the first protective layer exposed by the third opening.

9. The device of claim 8, wherein the bank covers an inclined surface of the second protective layer exposed by the third opening.

10. The device of claim 9, wherein the metal pattern is located on a same layer as the first electrode.

11. The device of claim 10, wherein the metal pattern surrounds the first electrode while being spaced apart from an outside of the first electrode.

12. The device of claim 11, wherein each of the plurality of first electrodes includes an inclined portion on an inclined surface of the second protective layer exposed by the first opening and configured to reflect light.

13. The device of claim 1, wherein the second non-emission area includes:
a planarization layer;
a first curved bank portion on the planarization layer;
a second curved bank portion on the planarization layer;
a first opening between the first curved bank portion and the second curved bank portion;
a common organic layer on the first curved bank portion, the second curved bank portion, and the first opening.

14. A display apparatus, comprising:
a first protective layer disposed on a substrate;
a second protective layer located on the first protective layer, the second protective layer having a plurality of first openings and a second opening;
a plurality of first electrodes located on the plurality of first openings;
a bank covering the second protective layer, the bank having a plurality of third openings exposing the plurality of first electrodes and a fourth opening overlapping the second opening; and
a common organic layer located in an area including the plurality of first electrodes and the bank, the common organic layer being disposed along a surface curve of the plurality of third openings and the fourth opening.

15. The display apparatus of claim 14, comprising:
a first pixel element;
a second pixel element; and
a pattern on the second protective layer, the pattern including a plurality of portions between the first pixel element and a second pixel element.

16. The display apparatus of claim 15 wherein a first portion of the pattern is a dielectric spacer on the bank.

17. The display apparatus of claim 16 wherein a second portion of the matter includes a metal pattern.

18. The display apparatus of claim 14, wherein the bank around the fourth opening covers an inclined surface of the second protective layer exposed through the second opening.

19. The display apparatus of claim 14, wherein the second opening is disposed on an outer periphery of each of two neighboring first electrodes among the plurality of first electrodes.

20. The display apparatus of claim 14, wherein each of the plurality of first electrodes includes an inclined portion disposed on an inclined surface of the second protective layer exposed by the first opening and configured to reflect light.

21. A device, comprising:
a substrate;
a first protective layer on the substrate;
a second protective layer on the first protective layer;
a plurality of first electrodes on the second protective layer;
a bank on the second layer, the bank having a first curved portion on the first protective layer and on the second protective layer and a second curved portion on the second protective layer;
a common organic layer on the first protective layer, on the first portion of the curved bank, and on the second portion of the curved bank.

22. The device of claim 21, comprising a pattern on the second protective layer, the pattern including a first portion that aligns with a non-curved portion of the bank.

23. The device of claim 22 wherein the pattern includes a second portion that aligns with an end of the first curved portion of the bank, the second portion of the pattern being a conductive material.

24. The device of claim 21 wherein the first curved portion is spaced from the second curved portion by a first electrode of the plurality of first electrodes.

25. The device of claim 24 comprising an emission layer on the common organic layer, the emission layer having an opening that exposes the second curved portion of the bank.

26. The device of claim 25 wherein the emission layer is partially overlapping the first portion of the curved bank.

27. A device, comprising:
a non-emission area of a pixel, the non-emission area including:
a planarization layer;
a first bank portion on the planarization layer;
a second bank portion on the planarization layer;
a first opening between the first bank portion and the second bank portion;
a common organic layer on the first bank portion, the second bank portion, and the first opening.

28. The device of claim 27 wherein the first and second bank portions are curved portions.

29. The device of claim 28 the non-emission area includes a pattern structure that interacts with the first bank portion and the second bank portion.

30. The device of claim 29 wherein the pattern structure includes a spacer structure on the first bank portion.

31. The device of claim 30 wherein the pattern structure includes a metal structure aligned with the second bank portion.

32. The device of claim 28 wherein the planarization layer includes a first portion separated from a second portion by the first opening.

33. The device of claim 27, comprising an emission area that is surrounded by the non-emission area and a transistor structure in the emission area, the non-emission area including a pattern structure.

34. The device of claim 33, comprising a substrate, the emission area and the non-emission area being on the substrate, the transistor includes an electrode on the substrate, and the pattern structure includes a spacer structure that overlaps at least a portion of the electrode.

35. The device of claim 27 wherein the non-emission area includes an electrode layer that overlaps a first portion of the planarization layer, is in the first opening, and overlaps a second portion of the planarization layer.

36. The device of claim 35 wherein the non-emission area includes a second opening in the electrode layer that is on the first portion of the planarization layer and a third opening in the electrode layer that is on the second portion of the planarization layer.

37. The device of claim 27, comprising:
a substrate, the planarization layer on the substrate;
an emission area on the substrate and surrounded by the non-emission area, the first bank portion being spaced from the second bank portion by the emission area;
an active layer on the substrate, the active layer being partially in the emission area and partially in the non-emission area; and
a pattern structure that interacts with the first bank portion.

38. The device of claim 37 wherein the pattern structure includes a spacer that overlaps an end of the active layer in the non-emission area.

39. The device of claim 38, comprising a trench in the planarization layer, wherein the spacer aligns with the trench and aligns with the end of the active layer.
